(19) United States
(12) Patent Application Publication
(10) Pub. No.: US 2024/0071943 A1
(43) Pub. Date: Feb. 29, 2024

(54) SEMICONDUCTOR PACKAGES

(71) Applicant: Samsung Electronics Co., Ltd., Suwon-si (KR)

(72) Inventor: Eunseok Song, Suwon-si (KR)

(21) Appl. No.: 18/455,854

(22) Filed: Aug. 25, 2023

(30) Foreign Application Priority Data
Aug. 29, 2022 (KR) 10-2022-0108713

(51) Int. Cl. H01L 23/538; H01L 23/00; H01L 23/498; H01L 23/64; H01L 25/065; H10B 80/00

(52) U.S. Cl. CPC H01L 23/5386; H01L 23/49822; H01L 23/5384; H01L 23/642; H01L 24/16; H01L 24/17; H01L 25/0655; H10B 80/00; H01L 21/4846; H01L 2224/16227; H01L 2224/16238; H01L 2224/1703; H01L 2924/1431; H01L 2924/1436; H01L 2924/381

(57) ABSTRACT

A semiconductor package includes a substrate having a cavity, a bridge chip structure in the cavity of the substrate and including a first bridge chip and a second bridge chip stacked on the first bridge chip, and a plurality of semiconductor chips spaced apart laterally on the substrate. Each of the plurality of semiconductor chips includes a first region that is electrically connected to the first bridge chip and a second region that is electrically connected to the second bridge chip.

### CROSS-REFERENCE TO RELATED APPLICATION

This application is based on and claims priority under 35 U.S.C. § 119 to Korean Patent Application No. 10-2022-0108713, filed on Aug. 29, 2022, in the Korean Intellectual Property Office, and the entire contents of the above-identified application are incorporated by reference herein.

### BACKGROUND

The present disclosure relates to semiconductor packages, and more particularly, relates to semiconductor packages having improved power integrity.

Recently, in the electronic product market, demand for portable devices is rapidly increasing, and accordingly, miniaturization and weight reduction of electronic components mounted on these electronic products are sought. For miniaturization and weight reduction of electronic components, a semiconductor package mounted thereon may be required to process high-capacity data while its volume becomes smaller.

To solve miniaturization and cost reduction demands, a semiconductor package using embedded multi-die interconnect bridge (EMIB) architectures provides high-density interconnects between heterogeneous dies on a single package by embedding a bridge (e.g., a silicon bridge) in a package substrate. However, because the area of the usual bridge is not large, the capacity of a capacitor inserted into the bridge is limited.

### SUMMARY

The present disclosure provides semiconductor packages having a capacitor of relatively large capacity, and into which a bridge that separately connects the capacitor to regions having different voltage levels inside a semiconductor chip may be inserted.

According to some aspects of the inventive concepts, there is provided a semiconductor package including a substrate having a cavity, a bridge chip structure in the cavity of the substrate and including a first bridge chip and a second bridge chip stacked on the first bridge chip, and a plurality of semiconductor chips spaced apart laterally on the substrate. Each semiconductor chip of the plurality of semiconductor chips includes a first region electrically connected to the first bridge chip and a second region electrically connected to the second bridge chip.

According to some aspects of the inventive concepts, there is provided a semiconductor package including aa substrate having a cavity, a bridge chip structure in the cavity of the substrate and including a first bridge chip and a second bridge chip stacked on the first bridge chip, a vertical connection structure that includes a plurality of vertical connection layers at different levels and that surrounds the bridge chip structure, a plurality of semiconductor chips spaced apart laterally on the substrate, and a connection bump structure between the substrate and each of the plurality of semiconductor chips. The connection bump structure may a plurality of first connection bumps electrically connected to the vertical connection structure, a plurality of second connection bumps each electrically connected to the bridge chip structure, and a plurality of third connection bumps. Each semiconductor chip of the plurality of semiconductor chips includes a first region electrically connected to the first bridge chip and a second region electrically connected to the second bridge chip.

According to some aspects of the inventive concepts, there is provided a semiconductor package including a substrate having a cavity, a bridge chip structure in the cavity of the substrate and including a first bridge chip and a second bridge chip stacked on the first bridge chip, an encapsulation layer on the substrate and encapsulating the bridge chip structure, a plurality of semiconductor chips spaced apart laterally on the substrate and each including a logic chip or a high bandwidth memory (HBM) chip, and a vertical connection structure that surrounds the bridge chip structure and that includes a plurality of vertical connection layers at different levels. Each semiconductor chip of the plurality of semiconductor chips includes a first region electrically connected to the first bridge chip and a second region electrically connected to the second bridge chip. The first region of each of the plurality of semiconductor chips may overlap partially the bridge chip structure, and the second region of each of the plurality of semiconductor chips may overlap completely the bridge chip structure. The first bridge chip may include a first capacitor electrically connected to the first region of each of the plurality of semiconductor chips, the second bridge chip may include a second capacitor electrically connected to the second region of each of the plurality of semiconductor chips, and each of the first capacitor and the second capacitor may include a metal-insulator-metal (MIM) capacitor, a deep trench capacitor (DTC), an integrated stack capacitor (ISC), or a combination thereof. The second bridge chip may include a through silicon via (TSV) that extends through the second bridge chip and to the first bridge chip, and the first bridge chip may be electrically connected to the first region of each of the plurality of semiconductor chips through the TSV. The vertical connection structure may be electrically connected to the first region of each of the plurality of semiconductor chips.

### BRIEF DESCRIPTION OF THE DRAWINGS

Some examples of embodiments of the inventive concepts will be more clearly understood from the following detailed description taken in conjunction with the accompanying drawings in which:

FIG. 1 is a plan view illustrating a schematic configuration of a semiconductor package according to some embodiments;

FIG. 2 is a cross-sectional view taken along line A-A′ of the semiconductor package of FIG. 1;

FIG. 3 is an enlarged view of a portion labeled ‘B’ of the semiconductor package of FIG. 2;

FIG. 4 is a cross-sectional view illustrating a bridge chip structure of FIG. 2;

FIG. 5 is a cross-sectional view illustrating a schematic configuration of a semiconductor package according to some embodiments;

FIG. 6 is an enlarged view of a portion labeled ‘D’ of the semiconductor package of FIG. 5;

FIG. 7 is a cross-sectional view illustrating a bridge chip structure of FIG. 5;

FIG. 8 is a cross-sectional view illustrating a schematic configuration of a semiconductor package according to some embodiments; and

FIGS. 9A, 9B, 9C, 9D, 9E, 9F, 9G, 9H, and 9I are cross-sectional views sequentially illustrating a method of manufacturing the semiconductor package illustrated in FIGS. 1 and 2.

### DETAILED DESCRIPTION OF THE EMBODIMENTS

Hereinafter, some embodiments of the inventive concepts will be described in detail with reference to the accompanying drawings. However, the inventive concepts should not be construed as being limited to the embodiments described herein and may be embodied in various other forms. The following embodiments are provided only to convey fully the scope of the inventive concept to those skilled in the art, rather than exhaustively define the inventive concepts.

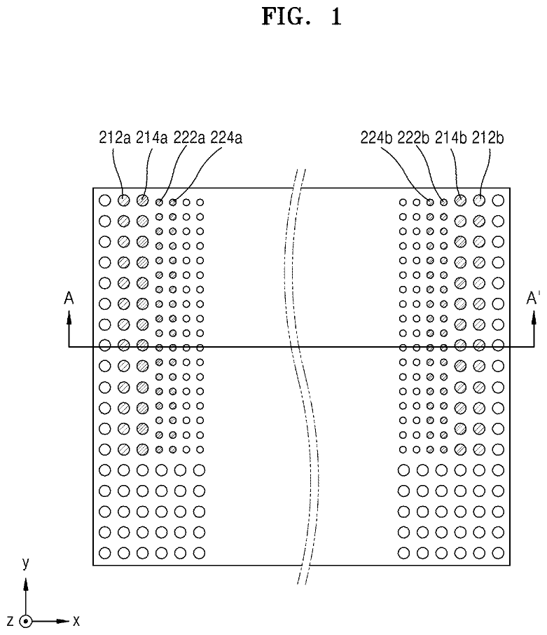

FIG. 1 is a plan view illustrating a schematic configuration of a semiconductor package 1 according to some embodiments.

Referring to FIG. 1, a first direction (x direction) and a second direction (y direction) may horizontally cross each other. For example, the first direction (x direction) and the second direction (y direction) may perpendicularly cross each other. A third direction (z direction) may cross both the first direction (x direction) and the second direction (y direction). For example, the third direction (z direction) may perpendicularly cross the first direction (x direction) and the second direction (y direction). Accordingly, the first direction (x direction), the second direction (y direction), and the third direction (z direction) may be orthogonal to each other.

The semiconductor package 1 according to some embodiments may include first connection bumps 212a and 212b, second connection bumps 214a and 214b, third connection bumps 224a and 224b, and fourth connection bumps 222a and 222b. In this regard, the first connection bumps 212a and 212b, the second connection bumps 214a and 214b, and the fourth connection bumps 222a and 222b may be power bumps that transmit power, and the third connection bumps 224a and 224b may be signal bumps that transmit signals. Specifically, a power supply voltage VDD, a ground voltage VSS, or a termination voltage may be supplied to the first connection bumps 212a and 212b, the second connection bumps 214a and 214b, and the fourth connection bumps 222a and 222b. Control signals such as input/output data signals and command signals may be transmitted to the third connection bumps 224a and 224b.

The plurality of first connection bumps 212a and 212b may be horizontally spaced apart from each other by a first pitch on a plane formed in the first direction (x direction) and the second direction (y direction). In this regard, the first pitch may be about 130 μm to about 170 μm. The plurality of third connection bumps 224a may be horizontally spaced apart from each other by a second pitch on the plane formed in the first direction (x direction) and the second direction (y direction). In this regard, the second pitch may be about 45 μm to about 65 μm.

According to some embodiments, the first connection bumps 212a and 212b may be larger than the second connection bumps 214a and 214b and/or the third connection bumps 224a and 22b.

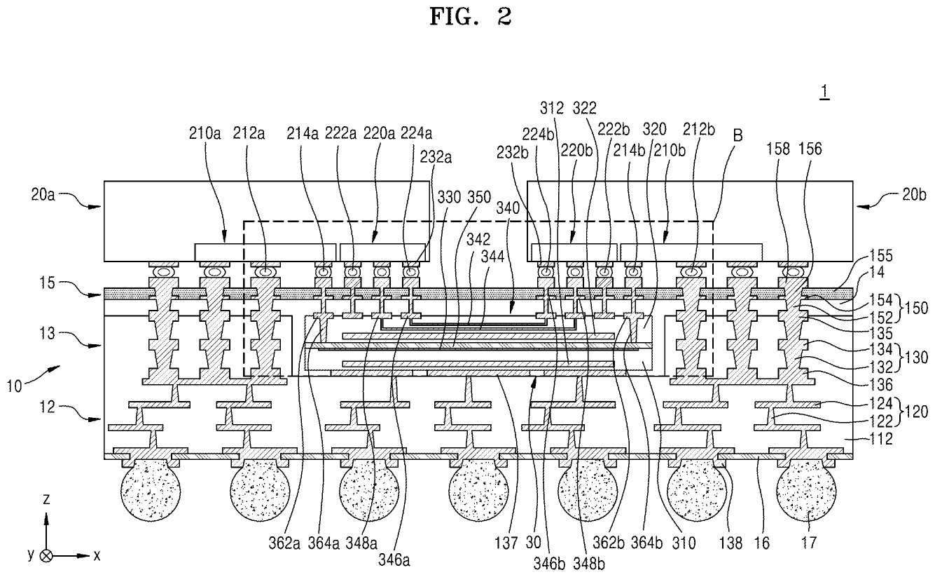

FIG. 2 is a cross-sectional view taken along line A-A′ of the semiconductor package 1 of FIG. 1.

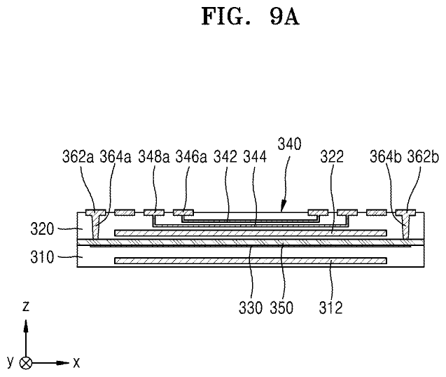

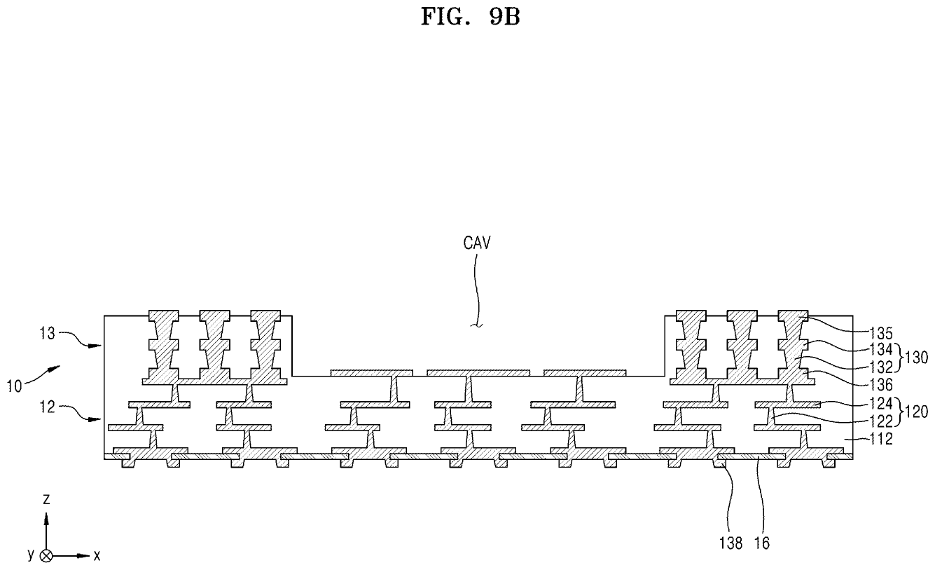

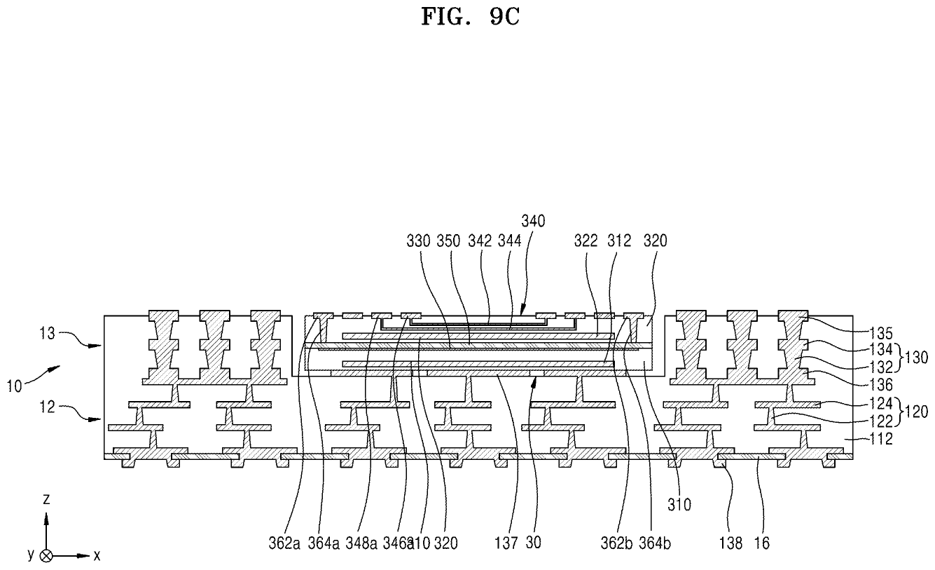

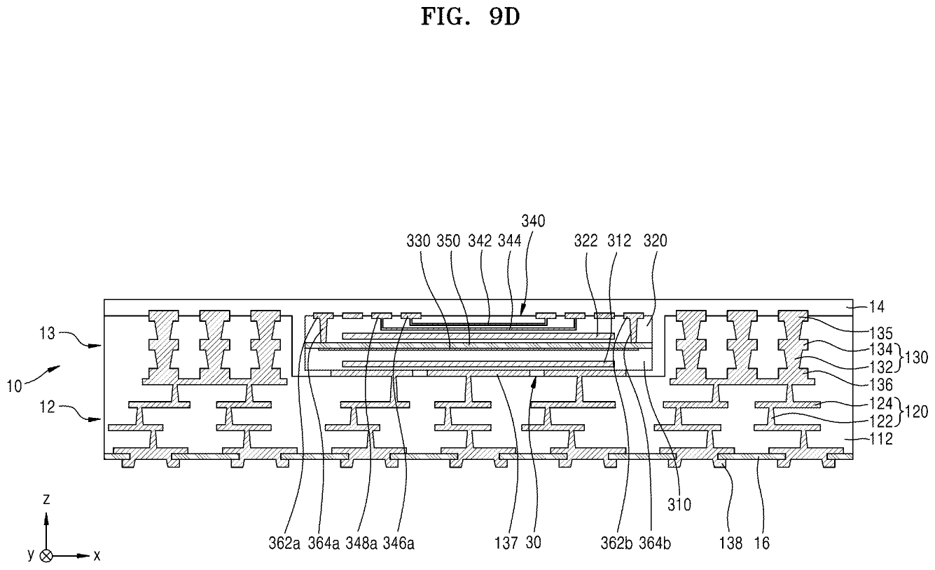

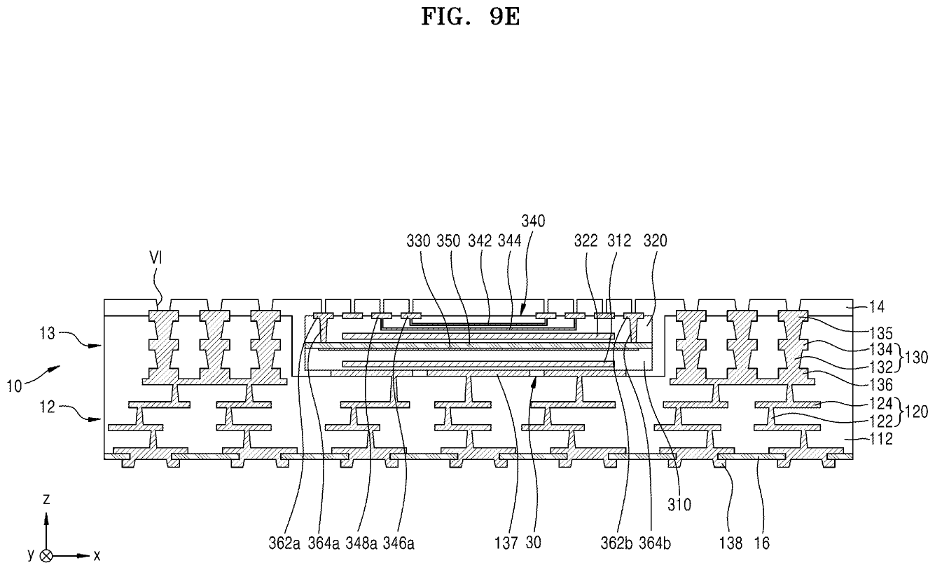

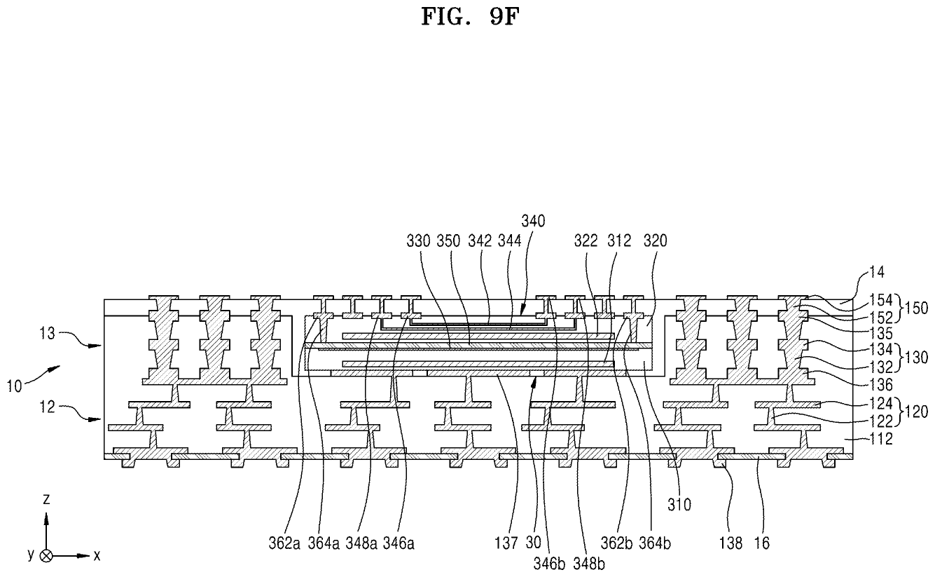

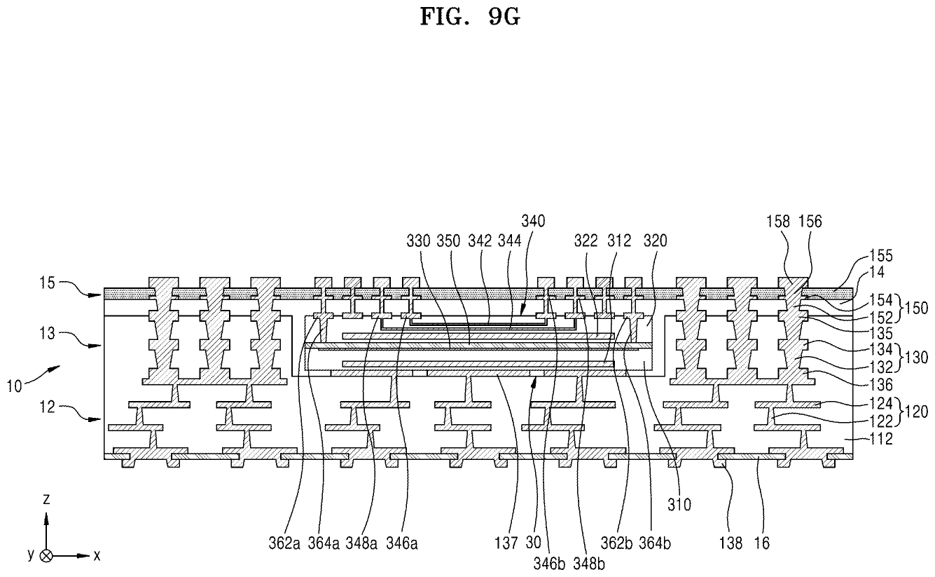

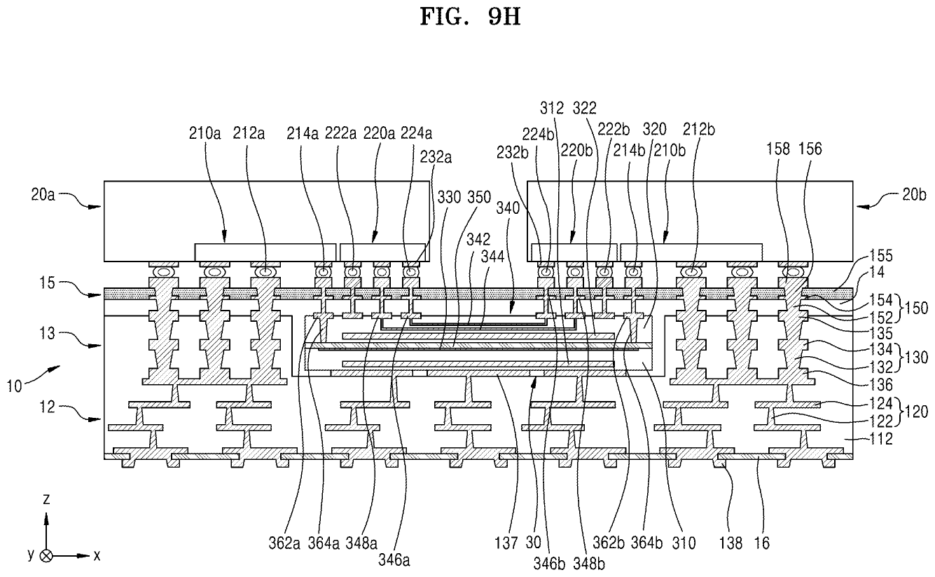

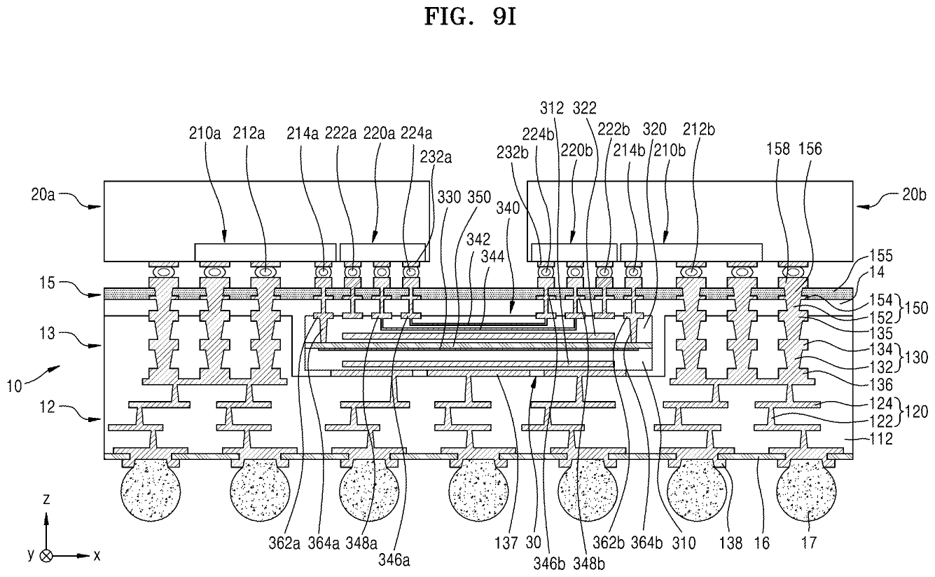

The semiconductor package 1 according to an embodiment may include a substrate 10, a plurality of semiconductor chips 20a and 20b, and a bridge chip structure 30. The bridge chip structure 30 may be accommodated in a cavity (see CAV of FIG. 9B) of the substrate 10. The upper redistribution structure 15 may be formed on the substrate 10 to electrically connect the substrate 10 to the plurality of semiconductor chips 20a and 20b.

The substrate 10 may include a lower wiring structure 12, a vertical connection structure 13, an encapsulation layer 14, a protective layer 16, an external connection terminal 17, and a body 112.

According to some embodiments, the body 112 may include a prepreg. In addition, the body 112 may be made of at least one material selected from phenol resin, epoxy resin, or polyimide. The body 112 may include at least one material selected from, for example, frame retardant 4 (FR-4), tetrafunctional epoxy, polyphenylene ether, epoxy/polyphenylene oxide, bismaleimide triazine (BT), thermount, cyanate ester, polyimide, or liquid crystal polymer.

Conductive patterns such as the lower wiring structure 12 and the vertical connection structure 13 may include, for example, metals such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru) or an alloy of the metals, but are not limited thereto. In some embodiments, the conductive pattern may be formed by stacking a metal or an alloy of a metal on a seed layer including copper, titanium, titanium nitride, or titanium tungsten.

According to some embodiments, the lower wiring structure 12 may be between a lower surface of the bridge chip structure 30 and a lower surface of the substrate 10. The lower wiring structure 12 may extend to the vertical connection structure 13 within the body 112 and may include the wiring pattern 120. The wiring pattern 120 may include conductive layers 124 and conductive vias 122 connecting the conductive layers 124.

The wiring pattern 120 may be electrically connected to a vertical connection pad 136 of the vertical connection structure 13. The wiring pattern 120 may be formed of the same material as the vertical connection pad 136.

According to some embodiments, the vertical connection structure 13 may be on the lower wiring structure 12. The vertical connection structure 13 may extend to the upper redistribution structure 15 within the body 112 and may include a redistributed vertical connection element 130. The vertical connection element 130 may include vertical connection layers 134, and vertical connection vias 132 connecting the vertical connection layers 134. Specifically, the vertical connection structure 13 may surround the bridge chip structure 30 and may include the plurality of vertical connection layers 134 at different levels. In this regard, the vertical connection structure 13 may be electrically connected to first regions 210a and 210b of a plurality of semiconductor chips 20a and 20b.

According to some embodiments, the vertical redistribution via 132 may have a tapered shape in which a horizontal width widens and extends from the lower side to the upper side. For example, horizontal widths of the plurality of vertical redistribution vias 132 may be wider as the plurality of vertical redistribution vias 132 are closer to the lower wiring structure 12. The vertical connection element 130 may be electrically connected to vertical connection pads 135 and 136. The vertical connection element 130 may be formed of the same material as the vertical connection pads 135 and 136.

According to some embodiments, the vertical connection structure 13 may include the vertical connection pads 135 and 136 electrically connected to the vertical connection element 130. The vertical connection pads 135 and 136 may be parts of the vertical connection layers 134 positioned on the upper surface or the lower surface of the vertical connection structure 13.

The protective layer 16 may be on a lower surface of the lower wiring structure 12. A lower surface of the protective layer 16 may have the same surface as a lower surface of an external pad 138. In other words, lower surfaces and the protective layer 16 and the external pads 138 may be coplanar. However, the lower surface of the protective layer 16 does not necessarily have the same surface as the lower surface of the external pad 138, and the lower surface of the protective layer 16 may be positioned higher than the lower surface of the external pad 138. The external pad 138 may be electrically isolated by a protective layer 151. The external connection terminal 17, for example, a solder ball, may be formed on the external pad 138.

The semiconductor package 1 may include the encapsulation layer 14. The encapsulation layer 14 may be on the substrate 10 to encapsulate the bridge chip structure 30. Specifically, the encapsulation layer 14 may be inside of a cavity (see CAV of FIG. 9B) and may cover the bridge chip structure 30 and the vertical connection structure 13.

The encapsulation layer 14 may be formed from a thermosetting resin such as an epoxy resin, a thermoplastic resin such as polyimide, or a resin including a reinforcing material such as an inorganic filler therein, specifically Ajinomoto build-up film (ABF), FR-4, BT, etc., but is not limited thereto. In some embodiments, the encapsulation layer 14 may be formed from a molding material such as an epoxy mold compound (EMC) or a photosensitive material such as a photoimagable encapsulant (PIE).

According to some embodiments, a capping layer 155 covering at least a portion of the encapsulation layer 14 and the upper redistribution structure 15 may be formed. The capping layer 155 may include a thermosetting resin such as an epoxy resin, a thermoplastic resin such as polyimide, or a resin including a reinforcing material such as an inorganic filler therein, specifically ABF, FR-4, BT, etc., but is not limited thereto.

According to some embodiments, the semiconductor package 1 may include the upper redistribution structure 15. The upper redistribution structure 15 may be on the vertical connection structure 13 and the bridge chip structure 30. Specifically, the upper redistribution structure 15 may be connected to the vertical connection pad 135. Also, the upper redistribution structure 15 may be formed in the encapsulation layer 14.

The upper redistribution structure 15 may extend to the vertical connection structure 13 within the encapsulation layer 14 and include a redistributed first upper redistribution element 150. The first upper redistribution element 150 may include first upper redistribution layers 154 and first upper redistribution vias 152 connecting the first upper redistribution layers 154. The first upper redistribution via 152 may have a tapered shape in which a horizontal width widens and extends from the lower side to the upper side. For example, horizontal widths of the plurality of first upper redistribution vias 152 may be narrower as the plurality of first upper redistribution vias 152 are closer to the vertical connection structure 13 or the bridge chip structure 30.

The first upper redistribution element 150 may be electrically connected to the vertical connection pad 135. The first upper redistribution element 150 may be formed of the same material as the vertical connection pad 135.

In addition, the upper redistribution structure 15 may extend from the inside and upper portion of the capping layer 155 to the first upper redistribution element 150, and include a second upper redistribution layer 158 and a second upper redistribution vias 156. The second upper redistribution via 156 may be electrically connected to the first upper redistribution layer 154. The second upper redistribution layer 158 and the second upper redistribution via 156 may be formed of the same material as the first upper redistribution element 150.

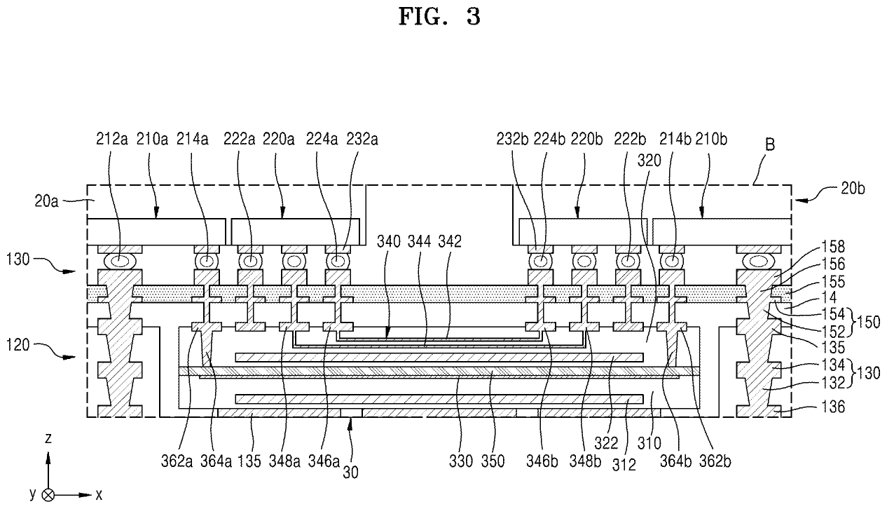

FIG. 3 is an enlarged view of a portion ‘B’ of the semiconductor package 1 of FIG. 2.

According to some embodiments, the semiconductor package 1 may include the plurality of semiconductor chips 20a and 20b arranged laterally on the substrate 10. The first semiconductor chip 20a may be electrically connected to the second semiconductor chip 20b. The plurality of semiconductor chips 20a and 20b may include the first regions 210a and 210b each electrically connected to a first bridge chip 310 and second regions 220a and 220b each electrically connected to a second bridge chip 320. The first regions 210a and 210b and the second regions 220a and 220b may each include a circuit pattern. The first regions 210a and 210b may be core power regions of a logic semiconductor chip.

According to some embodiments, the respective first regions 210a and 210b of the plurality of semiconductor chips 20a and 20b may overlap partially the bridge chip structure 30, and the respective second regions 220a and 220b of the plurality of semiconductor chips 20a and 20b may overlap completely the bridge chip structure 30. The second regions 220a and 220b may be physical layers of a logic semiconductor chip. The physical layer may convert data of a terminal into an electrical signal, transmit and receive the electrical signal, and interpret the electrical signal as the data in the logic semiconductor chip.

According to some embodiments, the plurality of semiconductor chips 20a and 20b may be logic chips, memory chips, or bridge chips. The memory chip may be, for example, a volatile memory chip such as dynamic random access memory (DRAM) or static random access memory (SRAM), or a non-volatile memory chip such as phase-change random access memory (PRAM), magnetic random access memory (MRAM), ferroelectric random access memory (FeRAM), or resistive random access memory (RRAM). The logic chip may be, for example, a microprocessor such as a central processing unit (CPU), a graphic processing unit (GPU), or an application processor (AP), an analog device, or a digital signal processor. Alternatively, the plurality of semiconductor chips 20a and 20b may be high bandwidth memory (HBM) chips with bandwidths increased by stacking DRAMs in several layers.

According to some embodiments, each of the first connection bumps 212a and 212b may be electrically connected to the vertical connection structure 13, and each of the second connection bumps 214a and 214b and the third connection bumps 224a and 224b may be electrically connected to the bridge chip structure 30. Specifically, the first connection bumps 212a and 212b may be respectively positioned between the plurality of semiconductor chips 20a and 20b and the vertical connection structure 13 to electrically connect each of the first regions 210a and 210b of the plurality of semiconductor chips 20a and 20b to the vertical connection structure 13. The second connection bumps 214a and 214b may be respectively positioned between the plurality of semiconductor chips 20a and 20b and the bridge chip structure 30 to electrically connect each of the second regions 220a and 220b of the plurality of semiconductor chips 20a and 20b to the first bridge chip 310. The third connection bumps 224a and 224b may be respectively positioned between the plurality of semiconductor chips 20a and 20b and the bridge chip structure 30 to electrically connect each of the second regions 220a and 220b of the plurality of semiconductor chips 20a and 20b to the second bridge chip 320.

According to some embodiments, the bridge chip structure 30 may include the first bridge chip 310 and the second bridge chip 320. The second bridge chip 320 may be stacked on the first bridge chip 310, and a lower surface of the second bridge chip 320 may be bonded to an upper surface of the first bridge chip 310. The second bridge chip 320 may include an upper second bridge circuit 342 and a lower second bridge circuit 344.

According to some embodiments, the bridge chip structure 30 may include first bridge pads 346a and 346b, second bridge pads 348a and 348b, and third bridge pads 362a and 362b formed on the second bridge chip 320. In this regard, the second bridge chip 320 may include through silicon vias (TSVs) 364a and 364b that extend through the second bridge chip 320 and extend to the first bridge chip 310. Accordingly, the first bridge chip 310 may be electrically connected to each of the first regions 210a and 210b of the plurality of semiconductor chips 20a and 20b through the TSVs 364a and 364b.

Although not shown in the drawing, a pad may be formed on the first bridge chip 310. Also, a bump may be formed below the pad formed on the first bridge chip 310 and the second bridge chip 320. The pad and the bump may electrically connect the TSVs 364a and 364b to the first bridge chip 310. Specifically, the TSVs 364a and 364b may penetrate the second bridge chip 320 and may electrically connect the third bridge pads 362a and 362b formed on the second bridge chip 320 to a first bridge circuit 330 included in the first bridge chip 310.

According to some embodiments, the first bridge pads 346a and 346b and the second bridge pads 348a and 348b may be signal pads. Accordingly, an input/output data signal and a control signal such as a command signal may be transmitted between the second bridge chip 320, the first semiconductor chip 20a, and the second semiconductor chip 20b through the first bridge pads 346a and 346b and the second bridge pads 348a and 348b.

According to some embodiments, the third bridge pads 362a and 362b may be power pads. Accordingly, the power supply voltage VDD, the ground voltage VSS, or a termination voltage may be supplied to the third bridge pads 362a and 362b.

According to some embodiments, the first bridge chip 310 may include the first bridge circuit 330 therein. The first bridge circuit 330 may be configured to electrically connect the first regions 210a and 210b of the plurality of semiconductor chips 20a and 20b through the upper redistribution structure 15. For example, the first region 210a of the first semiconductor chip 20a may be electrically connected to the first region 210b of the second semiconductor chip 20b through the first bridge circuit 330. The second bridge chip 320 may include a second bridge circuit 340 therein. The second bridge circuit 340 may be configured to electrically connect the second regions 220a and 220b of the plurality of semiconductor chips 20a and 20b. For example, the second region 220a of the first semiconductor chip 20a may be electrically connected to the second region 220b of the second semiconductor chip 20b through the second bridge circuit 340. Specifically, an upper second bridge circuit 342 and a lower second bridge circuit 344 of the second bridge circuit 340 may be configured to electrically connect the plurality of different third connection bumps 224a and 224b. Specifically, the first regions 210a and 210b of the first semiconductor chip 20a and the second semiconductor chip 20b may receive a voltage, etc. through the first bridge circuit 330. In addition, the second regions 220a and 220b of the first semiconductor chip 20a and the second semiconductor chip 20b may transmit input/output data signals and control signals such as command signals through the second bridge circuit 340.

According to some embodiments, the upper surface of the first bridge chip 310 may be a surface adjacent to an active surface of a semiconductor substrate constituting the first bridge chip 310, and the lower surface of the first bridge chip 310 may be a surface adjacent to an inactive surface of the semiconductor substrate constituting the first bridge chip 310. In addition, the upper surface of the second bridge chip 320 may be a surface adjacent to an active surface of a semiconductor substrate constituting the second bridge chip 320, and the lower surface of the second bridge chip 320 may be a surface adjacent to an inactive surface of the semiconductor substrate constituting the second bridge chip 320. The adhesive layer 350 may be configured to bond the upper surface of the first bridge chip 310 to the lower surface of the second bridge chip 320.

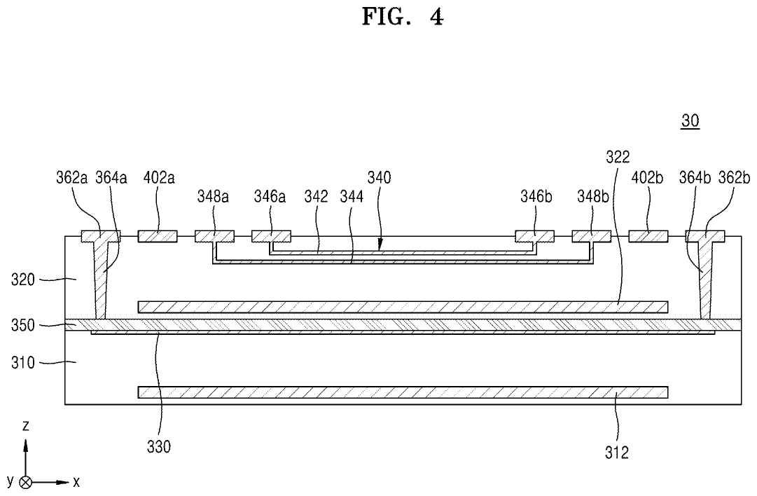

FIG. 4 is a cross-sectional view illustrating the bridge chip structure 30 of FIG. 2.

Referring to FIG. 4, the bridge chip structure 30 may include fourth bridge pads 402a and 402b formed on an upper surface of the bridge chip structure 30 and fourth bridge vias 404a and 404b formed therein. The fourth bridge chip pads 402a and 402b may be electrically connected to a first power transfer layer 406 through the fourth bridge vias 404a and 404b, respectively. According to an embodiment, the fourth bridge pads 402a and 402b may be power pads. The power supply voltage VDD, the ground voltage VSS, or a termination voltage may be supplied to the power pad.

Although not shown on the drawing, a capacitor may be included in each of the first bridge chip 310 and the second bridge chip 320. Accordingly, the first bridge chip 310 may include a first capacitor, and the second bridge chip 320 may include a second capacitor. In this regard, the first capacitor may be electrically connected to each of the first regions 210a and 210b of the plurality of semiconductor chips 20a and 20b through the first bridge circuit 330. The second capacitor may be electrically connected to each of the second regions 220a and 220b of the plurality of semiconductor chips 20a and 20b through the second bridge circuit 340. The first capacitor or the second capacitor may be a metal-insulator-metal (MIM) capacitor. The MIM capacitor may include voltage enhancement and transient noise improvements, thereby significantly improving the power integrity of the semiconductor package 1. In this regard, the first capacitor may be electrically connected to the first region 210a of the plurality of semiconductor chips 20a and 20b through the TSVs 364a and 364b and the first connection bumps 212a and 212b, and the second capacitor may be electrically connected to the second region 220a of the plurality of semiconductor chips 20a and 20b through the fourth bridge pads 402a and 402b and the fourth bridge vias 404a and 404b.

According to some embodiments, each of the first capacitor and the second capacitor may include not only a metal-insulator-metal (MIM) capacitor, but also a deep trench capacitor (DTC), an integrated stack capacitor (ISC), or a combination thereof.

The semiconductor package 1 according to the inventive concepts may include the bridge chip structure 30 in which the plurality of bridge chips 310 and 320 are stacked, thereby increasing the capacity of the capacitor included in the bridge chip structure 30, and providing the capacitor connected to each of the first regions 210a and 210b and the second regions 220a and 220b of semiconductor chips having different voltage levels.

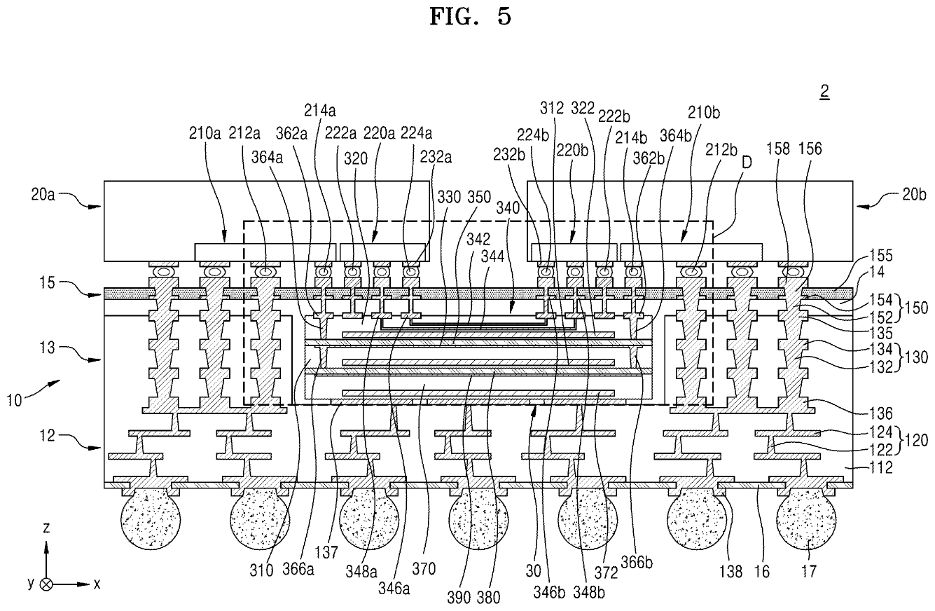

FIG. 5 is a cross-sectional view illustrating a schematic configuration of a semiconductor package 2 according to some embodiments.

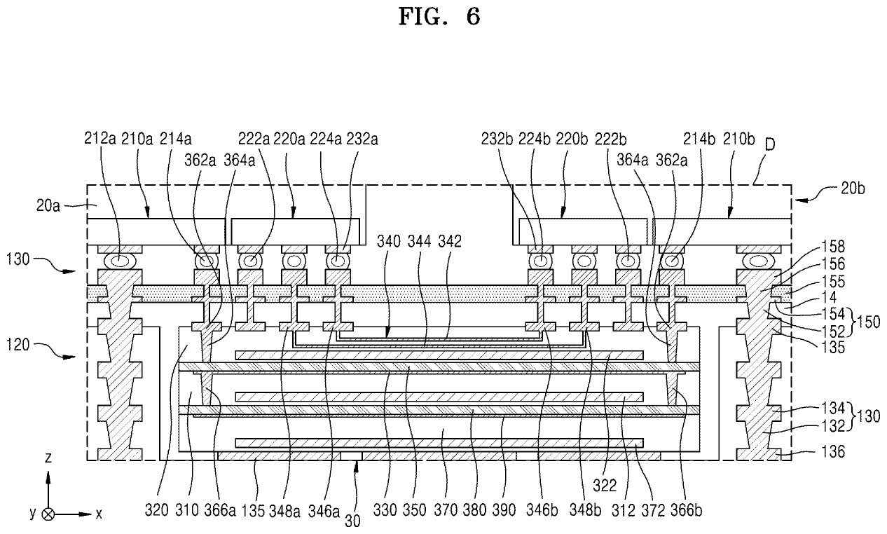

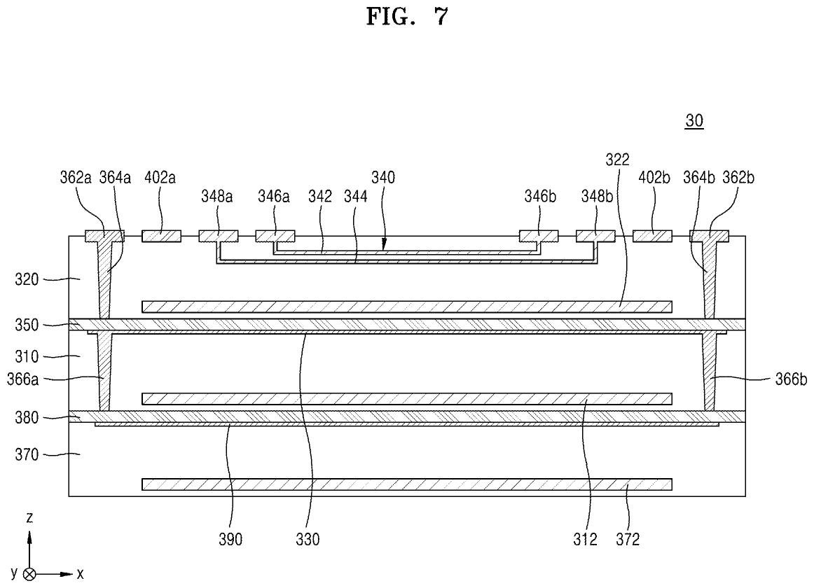

FIG. 6 is an enlarged view of a portion ‘D’ of the semiconductor package 2 of FIG. 5, and FIG. 7 is a cross-sectional view illustrating the bridge chip structure 30 of FIG. 5.

Specifically, the semiconductor package 2 may be the same as the semiconductor package 1 of FIG. 2, except that the bridge chip structure 30 further includes a third bridge chip 370. In FIG. 6, the same reference numerals as those of FIG. 2 are briefly described or omitted.

Referring to FIGS. 6 and 7, the bridge chip structure 30 may include the first bridge chip 310, the second bridge chip 320 having a lower surface bonded to an upper surface of the first bridge chip 310 on the first bridge chip 310, and the third bridge chip 370 having an upper surface bonded to a lower surface of the first bridge chip 310 below the first bridge chip 310. The third bridge chip 370 may include a third bridge circuit 390.

According to some embodiments, the first bridge chip 310 may include second TSVs 366a and 366b that extend through the first bridge chip 310 and extend to the third bridge chip 370. The second TSVs 366a and 366b may electrically connect the third bridge pads 362a and 362b that extend through the first bridge chip 310 and are formed on an upper portion of the second bridge chip 320 to the third bridge circuit 390 included in the third bridge chip 370.

According to some embodiments, the third bridge chip 370 may include the third bridge circuit 390 therein. The third bridge circuit 390 may be configured to electrically connect the first regions 210a and 210b of the plurality of semiconductor chips 20a and 20b through the upper redistribution structure 15.

According to some embodiments, an upper surface of the third bridge chip 370 may be an active surface, and a lower surface of the third bridge chip 370 may be an inactive surface. In addition, an upper surface of the first bridge chip 310 may be an active surface, and a lower surface of the first bridge chip 310 may be an inactive surface. The second adhesive layer 380 may be configured to bond an upper surface of the third bridge chip 310 to a lower surface of the second bridge chip 320.

Although not shown on the drawing, the third bridge chip 370 may also include a capacitor therein like the bridge chip structure 30 shown in FIG. 4. Accordingly, the third bridge chip 370 may include a third capacitor. In this regard, the third capacitor may be electrically connected to the first region 210a of the plurality of semiconductor chips 20a and 20b through the TSVs 364a and 364b, the second TSVs 366a and 366b, and the first connection bumps 212a and 212b.

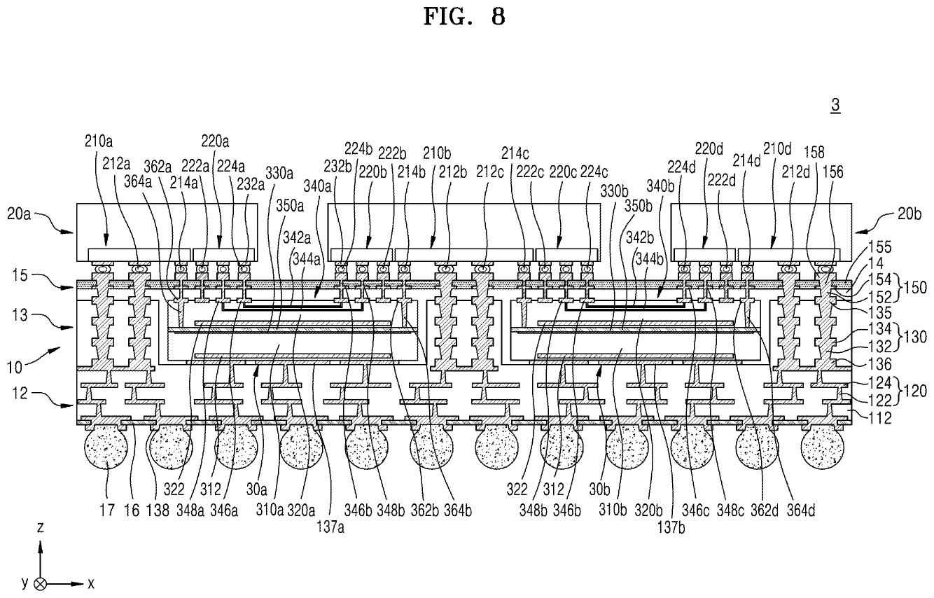

FIG. 8 is a cross-sectional view illustrating a schematic configuration of a semiconductor package 3 according to some embodiments.

Specifically, the semiconductor package 3 may be the same as the semiconductor package 1 of FIG. 2, except that the semiconductor package 3 may further include a third semiconductor chip 20c and a second bridge chip structure 30b. In FIG. 6, the same reference numerals as those of FIG. 2 are briefly described or omitted.

Referring to FIG. 8, the semiconductor package 3 may include a plurality of semiconductor chips 20a, 20b, and 20c arranged laterally on the substrate 10. In this regard, the third semiconductor chip 20c may be laterally spaced apart from the second semiconductor chip 20b. The third semiconductor chip 20c may be electrically connected to the second semiconductor chip 20b. The third semiconductor chip 20c may include a first region 210d and a second region 220d.

According to some embodiments, the second bridge chip structure 30b may include a first bridge chip 310b and a second bridge chip 320b having a lower surface bonded to an upper surface of the first bridge chip 310b on the first bridge chip 310b. The first bridge chip 310b may include a first bridge circuit 330b. The second bridge chip 320b may include an upper second bridge circuit 342b and a lower second bridge circuit 344b.

According to some embodiments, the second semiconductor chip 20b and the third semiconductor chip 20c may be electrically connected to each other through the second bridge chip structure 30b. In addition, each of the first bridge chip 310b and the second bridge chip 320b included in the second bridge chip structure 30b may include a capacitor. Each of the first bridge chip 310a and the second bridge chip 320a included in the first bridge chip structure 30a as well as the second bridge chip structure 30b may include a capacitor. Accordingly, a capacitor of a large capacity may be provided to each of the semiconductor chips 20a, 20b, and 20c, and a capacitor optimized for the voltage required by each of the first regions 210a, 210b, and 210d and the second regions 220a, 220b, 220c, and 220d of the semiconductor chips 20a, 20b, and 20c may be provided.

FIGS. 9A to 9I are cross-sectional views sequentially illustrating a method of manufacturing the semiconductor package 2 illustrated in FIGS. 1 and 2.

Specifically, in FIGS. 9A to 9I, the same reference numerals as in FIGS. 1 and 2 denote the same members. In FIGS. 9A to 9I, the same descriptions as in FIGS. 1 and 2 are briefly given or omitted.

Referring to FIG. 9A, the second bridge circuit 340 may be formed inside the second bridge chip 320. The second bridge circuit 340 may include the upper second bridge circuit 342 and the lower second bridge circuit 344. First, after the lower second bridge circuit 344 is formed, the upper second bridge circuit 342 may be formed. The second bridge circuit 340 is formed by a photolithography process, and thus, the second bridge chip 320 may improve a degree of design freedom. The first bridge pads 346a and 346b (see FIG. 2) may be electrically connected to each other by the upper second bridge circuit 342. The second bridge pads 348a and 348b (see FIG. 2) may be electrically connected to each other by the lower second bridge circuit 344.

Thereafter, the TSVs 364a and 364b penetrating the second bridge chip 320 may be formed. Although not shown in the drawing, a pad may be formed on the first bridge chip 310. Also, a bump may be formed below the pad formed on the first bridge chip 310 and the second bridge chip 320. The pad and the bump may electrically connect the TSVs 364a and 364b to the first bridge chip 310.

According to some embodiments, the first bridge circuit 330 may be formed inside the first bridge chip 310. Thereafter, the first bridge chip 310 may be bonded to the second bridge chip 320 using the adhesive layer 350. Although the drawing shows that the first bridge chip 310 is bonded to the second bridge chip 320 after the TSVs 364a and 364b are formed on the second bridge chip 320, the TSVs 364a and 364b may be formed on the second bridge chip 320 after the first bridge chip 310 is bonded to the second bridge chip 320. The third bridge pads 362a and 362b may be electrically connected to each other through the TSVs 364a and 364b and the first bridge circuit 330.

Referring to FIG. 9B, the substrate 10 is prepared. The substrate 10 may be, for example, a printed circuit board, and may include the lower wiring structure 12 and the vertical connection structure 13.

Referring to FIG. 9C, the bridge chip structure 30 may be in a cavity CAV formed between the vertical connection structures 13 of the substrate 10. The bridge chip structure 30 may be on a bottom surface of the substrate 10 defining the cavity CAV, and the bridge chip structure 30 may be surrounded by an inner wall of the substrate 10 defining the cavity CAV.

Referring to FIGS. 9D and 9E, after the bridge chip structure 30 is arranged in the cavity CAV of the substrate 10, the encapsulation layer 14 that encapsulates the bridge chip structure 30 and the vertical connection structure 13 may be formed. Thereafter, a via hole VI may be formed on the vertical connection structure 13 and the bridge chip structure 30 by removing a part of the encapsulation layer 14. The part of the encapsulation layer 14 may be removed through a laser drilling process and/or an etching process.

Referring to FIG. 9F, the first upper redistribution via 152 may be formed in the via hole VI formed in the encapsulation layer 14. Thereafter, the first upper redistribution element 150 may be completed by forming the first upper redistribution layer 154 on an upper end of the first upper redistribution via 152. The first upper redistribution element 150 may be electrically isolated from each other by the encapsulation layer 14. In some embodiments, the first upper redistribution via 152 and the first upper redistribution layer 154 may be integrally formed through a plating process.

Referring to FIG. 9G, after the first upper redistribution element 150 is formed, the capping layer 155 may be formed. Thereafter, after a via hole is formed in the capping layer 155, the second upper redistribution via 156 filling the via hole of the capping layer 155 and the second upper redistribution layer 158 extending along an upper surface of the capping layer 155 may be formed. In some embodiments, the second upper redistribution via 156 and the second upper redistribution layer 158 may be integrally formed through a plating process.

Referring to FIG. 9H, the plurality of semiconductor chips 20a and 20b may be on the substrate 10. In this case, the plurality of bumps 212a, 212b, 214a, 214b, 222a, 222b, 224a, and 224b may be positioned between the substrate 10 and the plurality of semiconductor chips 20a and 20b to electrically and physically connect electrically and physically connect the substrate 10 and the plurality of semiconductor chips 20a and 20b. Specifically, the first connection bumps 212a and 212b may be configured to electrically connect the first regions 210a and 210b of the plurality of semiconductor chips 20a and 20b to the vertical connection structure 13. The second connection bumps 214a and 214b may be configured to electrically connect the first bridge chip 310 to the first regions 210a and 210b of the plurality of semiconductor chips 20a and 20b. The third connection bumps 224a and 224b may be configured to electrically connect the second bridge chip 320 to the second regions 220a and 220b of the plurality of semiconductor chips 20a and 20b.

Referring to FIG. 9I, a first external connection terminal 175, for example, a solder ball, may be formed on an external pad 138. Thereafter, when the external connection terminal 17, for example, a solder ball, is formed on the external pad 153, the fan-out semiconductor package 100 may be manufactured.

While the inventive concept has been particularly shown and described with reference to embodiments thereof, it will be understood that various changes in form and details may be made therein without departing from the spirit and scope of the following claims.

What is claimed is:

1. A semiconductor package comprising:
a substrate having a cavity;
a bridge chip structure in the cavity of the substrate and comprising a first bridge chip and a second bridge chip stacked on the first bridge chip; and
a plurality of semiconductor chips spaced apart laterally on the substrate,
wherein each semiconductor chip of the plurality of semiconductor chips comprises a first region that is electrically connected to the first bridge chip and a second region that is electrically connected to the second bridge chip.

2. The semiconductor package of claim 1, wherein:
the first bridge chip includes a first capacitor that is electrically connected to the first region of each semiconductor chip of the plurality of semiconductor chips, and
the second bridge chip includes a second capacitor that is electrically connected to the second region of each semiconductor chip of the plurality of semiconductor chips.

3. The semiconductor package of claim 2, wherein each of the first capacitor and the second capacitor includes a metal-insulator-metal (MIM) capacitor, a deep trench capacitor (DTC), an integrated stack capacitor (ISC), or a combination thereof.

4. The semiconductor package of claim 1, wherein
the first region of each semiconductor chip of the plurality of semiconductor chips overlaps the bridge chip structure partially, and
the second region of each semiconductor chip of the plurality of semiconductor chips overlaps the bridge chip structure completely.

5. The semiconductor package of claim 1, further comprising a vertical connection structure that surrounds the bridge chip structure and includes a plurality of vertical connection layers at different levels,
wherein the vertical connection structure is electrically connected to the first region of each semiconductor chip of the plurality of semiconductor chips.

6. The semiconductor package of claim 1, wherein
the second bridge chip includes a through silicon via (TSV) that extends through the second bridge chip and extends to the first bridge chip, and
the first bridge chip is electrically connected to the first region of each semiconductor chip of the plurality of semiconductor chips through the TSV.

7. The semiconductor package of claim 1, wherein the first bridge chip includes a first bridge circuit that electrically connects the first regions of the plurality of semiconductor chips.

8. The semiconductor package of claim 1, wherein the second bridge chip includes a second bridge circuit that electrically connects the second regions of the plurality of semiconductor chips.

9. The semiconductor package of claim 1, wherein each semiconductor chip of the plurality of semiconductor chips includes a logic chip or a high bandwidth memory (HBM) chip.

10. The semiconductor package of claim 1, further comprising an encapsulation layer on the substrate that surrounds the bridge chip structure.

11. A semiconductor package comprising:
a substrate having a cavity;
a bridge chip structure in the cavity of the substrate and comprising a first bridge chip and a second bridge chip stacked on the first bridge chip;
a vertical connection structure comprising a plurality of vertical connection layers at different levels, the vertical connection structure surrounding the bridge chip structure;
a plurality of semiconductor chips spaced apart laterally on the substrate; and
a connection bump structure between the substrate and each semiconductor chip of the plurality of semiconductor chips, the connection bump structure comprising a plurality of first connection bumps electrically connected to the vertical connection structure, a plurality of second connection bumps each electrically connected to the bridge chip structure, and a plurality of third connection bumps each electrically connected to the bridge chip structure,
wherein each semiconductor chip of the plurality of semiconductor chips comprises a first region electrically connected to the first bridge chip and a second region electrically connected to the second bridge chip.

12. The semiconductor package of claim 11, wherein each of the plurality of first connection bumps is between the first region of each semiconductor chip of the plurality of semiconductor chips and the vertical connection structure, and is electrically connected to the first region.

13. The semiconductor package of claim 11, wherein each of the plurality of second connection bumps is between the first region of each semiconductor chip of the plurality of semiconductor chips and the bridge chip structure, and is electrically connected to the second region.

14. The semiconductor package of claim 11, wherein each of the plurality of third connection bumps is between the second region of each semiconductor chip of the plurality of semiconductor chips and the bridge chip structure, and is electrically connected to the second region.

15. The semiconductor package of claim 11, wherein the plurality of first connection bumps are horizontally spaced apart from each other by a first pitch, and
wherein the first pitch is about 130 μm to about 170 μm.

16. The semiconductor package of claim 11, wherein the plurality of third connection bumps are horizontally spaced apart from each other by a second pitch, and
wherein the second pitch is about 45 μm to about 65 μm.

17. The semiconductor package of claim 11, wherein each of the plurality of first connection bumps is larger than each of the plurality of second connection bumps and each of the plurality of third connection bumps.

18. The semiconductor package of claim 11, wherein the second bridge chip includes a through silicon via (TSV) that extends through the second bridge chip and extends to the first bridge chip, and wherein the first bridge chip is electrically connected to each of the plurality of second connection bumps through the TSV.

19. A semiconductor package comprising:
a substrate having a cavity;
a bridge chip structure in the cavity of the substrate and comprising a first bridge chip and a second bridge chip stacked on the first bridge chip;
an encapsulation layer on the substrate that surrounds the bridge chip structure;
a plurality of semiconductor chips spaced apart laterally on the substrate and each comprising a logic chip or a high bandwidth memory (HBM) chip; and
a vertical connection structure that surrounds the bridge chip structure and including a plurality of vertical connection layers at different levels,
wherein each semiconductor chip of the plurality of semiconductor chips comprises a first region that is electrically connected to the first bridge chip and a second region that is electrically connected to the second bridge chip,
wherein the first region of each of the plurality of semiconductor chips overlaps the bridge chip structure partially, and the second region of each of the plurality of semiconductor chips overlaps the bridge chip structure completely,
wherein the first bridge chip comprises a first capacitor that is electrically connected to the first region of each of the plurality of semiconductor chips, the second bridge chip comprises a second capacitor that is electrically connected to the second region of each of the plurality of semiconductor chips, and each of the first capacitor and the second capacitor comprises a metal-insulator-metal (MIM) capacitor, a deep trench capacitor (DTC), an integrated stack capacitor (ISC), or a combination thereof,
wherein the second bridge chip includes a through silicon via (TSV) that extends through the second bridge chip and extends to the first bridge chip, and the first bridge chip is electrically connected to the first region of each of the plurality of semiconductor chips through the TSV, and
wherein the vertical connection structure is electrically connected to the first region of each of the plurality of semiconductor chips.

20. The semiconductor package of claim 19, wherein the first bridge chip includes a first bridge circuit that electrically connects the first regions of the plurality of semiconductor chips, and wherein the second bridge chip includes a second bridge circuit configured that electrically connects the second regions of the plurality of semiconductor chips.
